(19) United States
(12) Patent Application Publication
(10) Pub. No.: US 2024/0055310 A1
(43) Pub. Date: Feb. 15, 2024

(54) SEMICONDUCTOR PACKAGE

(71) Applicant: HUAWEI TECHNOLOGIES CO., LTD., Shenzhen (CN)

(72) Inventor: Jürgen HÖGERL, Munich (DE)

(21) Appl. No.: 18/483,281

(22) Filed: Oct. 9, 2023

Related U.S. Application Data
(63) Continuation of application No. PCT/EP2021/059247, filed on Apr. 9, 2021.

(51) Int. Cl. H01L 23/31; H01L 23/367; H01L 23/498; H01L 23/00; H01L 21/56

(52) U.S. Cl. CPC H01L 23/3107; H01L 23/367; H01L 23/49822; H01L 23/49866; H01L 24/29; H01L 24/32; H01L 21/565; H01L 2224/2957; H01L 2224/32225; H01L 2924/13055; H01L 2924/13091

(57) ABSTRACT

A semiconductor package includes a first substrate, a semiconductor chip, a leadframe comprising at least one lead, and an encapsulant. A lower main face of the encapsulant includes a first portion extending in a first plane, a second portion extending in a second plane, a third portion extending in a first transition zone between the first plane and the second plane, and a fourth portion extending in a second transition zone between the second plane and the at least one lead. Both the first portion of the encapsulant and a lower main face of the first substrate extend in the first plane forming a lower heat dissipation surface of the package. The second portion, the third portion and the fourth portion of the encapsulant are dimensioned so as to keep a first predefined minimum distance between the first portion of the encapsulant and the at least one lead.

### CROSS-REFERENCE TO RELATED APPLICATIONS

This application is a continuation of International Application No. PCT/EP2021/059247, filed on Apr. 9, 2021, the disclosure of which is hereby incorporated by reference in its entirety.

### FIELD

The present disclosure relates to a semiconductor package and a method for producing a semiconductor package. The disclosure further relates to isolation requirements for power packages or modules, in particular for double side cooled (DSC) power modules but also for single side cooled (SSC) power modules.

### BACKGROUND

For power packages or power modules certain rules apply to ensure proper insulation inside and outside of the package between areas carrying current. For the external insulation the IEC60664 standard is defining insulation distances with respect to air insulation distance and creepage distance. The creepage distance is dominated by the surface insulation behavior and the surface quality of the insulating material. The surface insulation behavior can be described by the Comparative Tracking Index (CTI). The surface quality can be described by the pollution degree of the insulating material. In the IEC60664 standard, minimum creepage distances are defined based on the given voltage, the pollution degree and the material group of the insulating material.

The surface insulation behavior of a mold compound is mainly related to the resin and less to the filler particles. At the surface of a semiconductor the presence of resin is higher than in the bulk, so there is a strong dependency on the surface condition. Therefore, any modification of the surface of the mold body after molding, e.g. by grinding or other thinning techniques, results in different conditions of the surface insulation behavior and hence changed insulation requirements. In particular, the needed creepage distances will extend which is in contradiction to the design constraints for package and system which are calling for compact designs.

### SUMMARY

Aspects of the present disclosure provide a solution for a power package or power module as described above without the above described disadvantages.

Embodiments of the present disclosure provide a power package whose surface insulation behavior is independent of surface modification steps such as grinding or other thinning techniques.

Embodiments of the present disclosure are based on the idea to separate the surface insulation areas of the power package into two areas. A first one which will see physical or other changes after molding and a second one which will stay unaffected. For the second area being unaffected, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package.

Embodiments of the present disclosure provide a novel package outline design which ensures desired surface insulation behavior in case that the package needs to undergo mechanical treatment after molding, e.g. to increase flatness of the integrated heat spreader. This novel package outline design ensures that on both sides, e.g. for DSC package (but also on only one side, e.g. for SSC package) of the package the integrated heat sinks to be flattened are elevated towards the remaining package body.

Using this novel package outline design ensures that only the area to be treated will see changes in surface structure which will likely end up in lower surface isolation robustness. The area which will not be affected by the mechanical treatment as described above can be designed according to the requirements of the IEC60664 standard. This novel solution ensures that whatever will happen to the treated area has no influence on the compliance of the package with the insulation requirements needed for save and reliable operation of the package.

In order to describe the embodiments in detail, the following terms, abbreviations and notations will be used:
CTI comparative tracking index
DSC double side cooling (package)
SSC single side cooling (package)
DC direct current
AC alternating current
TIM thermal interface material
MOSFET Metal-Oxide Semiconductor Field Effect Transistor
IGBT insulated gate bipolar transistor

In this disclosure, insulation distances, in particular creepage distances are described. For the external isolation the IEC60664 standard is defining insulation distances with respect to air insulation distances and creepage distances. While the air insulation distance is the simple straight distance between two pins and mainly dominated by the surrounding environment (e.g. air pressure or humidity), the creepage distance is a more complex topic. It is dominated by the surface insulation behavior of the insulating material and the quality of the surface. The surface insulation behavior of the insulating material is determined by a test specimen and the value given is the comparative tracking index (CTI) dividing the insulation behavior in subclasses, where a CTI of 600 is considered as the most robust one. The quality (or cleanliness) of the surface is described by the pollution degree and is usually set to 2 for automotive inverter systems (closed box with limited residues or particles).

Table F.4 of the IEC 60664 standard (see below) illustrates the minimum creepage distance between two pins based on given voltage (e.g. 600V in one example), a pollution degree (e.g. 2 in one example) and the material group, which is linked to the CTI of the mold compound. For material group I, CTI is 600; for material group II, CTI is between 400 and 600; and for material group III, CTI is below 400.

The highest uncertainty is related to the CTI as the test specimen and the reality may differ from each other. The surface isolation behavior of a mold compound is mainly related to the resin and less to the filler particles. At the surface of a semiconductor the presence of resin is higher than in the bulk, so there is a strong dependency on the surface condition. The CTI measurement is very simple by dropping a conductive liquid (e.g. salt solution) between two electrodes touching the surface of the test specimen while it is evaluated when a temporary conductive path is starting to establish.

Table F.4 of the IEC 60664 standard

| | Minimum creepage distances | | | | | | | | |
|---|---|---|---|---|---|---|---|---|---|
| | Printed wiring material | | | | | | | | |
| | Pollution degree | | | | | | | | |
| | 1 | 2 | 1 | 2 | | | 3 | | |
| | | All | | | | | | | |
| | | material | | | | | | | |
| | All | groups | All | Material | Material | Material | Material | Material | Material |
| Voltage | material | except | material | group | group | group | group | group | group |
| r.m.s. ¹⁾ | groups | IIIb | groups | I | II | III | I | II | III ²⁾ |
| V | mm | mm | mm | mm | mm | mm | mm | mm | mm |
| 25 | 0.025 | 0.040 | 0.125 | 0.500 | 0.500 | 0.500 | 1.250 | 1.250 | 1.250 |
| 32 | 0.025 | 0.040 | 0.14 | 0.53 | 0.53 | 0.53 | 1.30 | 1.30 | 1.30 |
| 40 | 0.025 | 0.040 | 0.16 | 0.56 | 0.80 | 1.10 | 1.40 | 1.60 | 1.80 |
| 50 | 0.025 | 0.040 | 0.18 | 0.60 | 0.85 | 1.20 | 1.50 | 1.70 | 1.90 |
| 63 | 0.040 | 0.063 | 0.20 | 0.63 | 0.90 | 1.25 | 1.60 | 1.80 | 2.00 |
| 80 | 0.063 | 0.100 | 0.22 | 0.67 | 0.96 | 1.30 | 1.70 | 1.90 | 2.10 |
| 100 | 0.100 | 0.160 | 0.25 | 0.71 | 1.00 | 1.40 | 1.80 | 2.00 | 2.20 |
| 125 | 0.160 | 0.250 | 0.28 | 0.75 | 1.06 | 1.60 | 1.90 | 2.10 | 2.40 |
| 160 | 0.250 | 0.400 | 0.32 | 0.80 | 1.10 | 1.60 | 2.00 | 2.20 | 2.50 |
| 200 | 0.400 | 0.630 | 0.42 | 1.00 | 1.40 | 2.00 | 2.50 | 2.80 | 3.20 |
| 250 | 0.560 | 1.000 | 0.56 | 1.25 | 1.80 | 2.50 | 3.20 | 3.60 | 4.00 |
| 320 | 0.75 | 1.60 | 0.75 | 1.60 | 2.20 | 3.20 | 4.00 | 4.50 | 5.00 |
| 400 | 1.0 | 2.0 | 1.0 | 2.0 | 2.8 | 4.0 | 5.0 | 5.6 | 6.3 |
| 500 | 1.3 | 2.6 | 1.3 | 2.5 | 3.6 | 5.0 | 6.3 | 7.1 | 8.0 |
| 630 | 1.8 | 3.2 | 1.8 | 3.2 | 4.6 | 6.3 | 8.0 | 9.0 | 10.0 |
| 800 | 2.4 | 4.0 | 2.4 | 4.0 | 5.6 | 8.0 | 10.0 | 11.0 | 12.5 |
| 1000 | 3.2 | 5.0 | 3.2 | 5.0 | 7.1 | 10.0 | 12.5 | 14.0 | 16.0 |

Any modification of the surface of the mold body after molding, e.g. by grinding or other thinning techniques, results in different conditions of the surface insulation behavior and hence changed insulation requirements. In particular, the needed creepage distances will extend which is in contradiction to the design constraints for package and system which are calling for compact designs.

In this disclosure, double side cooling (DSC) packages but also single side cooling (SSC) packages are described. The conventional single side cooling (SSC) package is covered with an insulating mold. The heat dissipation path of the package is mainly its bottom drain side cooling plate. On the other side, the double side cooling (DSC) package has a top source side cooling plate in addition to the bottom drain side plate. These cooling plates contribute in reducing the thermal resistance. As heat is removed from both, the top and bottom surfaces, a double side cooling package utilizes the heat sink efficiently. These double side cooling packages are designed for high-efficient cooling to achieve the highest level of energy that can be switched with such a system.

In this disclosure, assembly technologies are described. Assembly technologies achieve a flatness and/or parallelism of the Cu heat spreader layers (1 layer for SSC and 2 layers for DSC) of 100 μm or less. A flexible thermal interface material (TIM/usually Al₂O₃ particles and Silicon grease) can be used to compensate the deviations with poor thermal conductivity (e.g. 1 W/mK). The TIM may for example be applied in between the integrated Cu heat spreaders and the upper and lower heat spreader. On the other hand, more sophisticated thermal interconnect layers like soldering, sintering or phase change materials have (significantly) lower gap bridging capabilities and require compensation of the thickness tolerance, flatness and parallelism of each individual module and on the deviations from module to module when several modules are put into a row, for example. As a consequence, thinning or grinding of the surfaces of the modules may be needed.

When applying thinning or grinding procedures, certain areas of the mold compound may be treated, i.e. reduced in size, thereby causing a change in the surface insulation behavior by e.g. exposing more filler particles to the surface or smearing Cu residues into the mold surface. The disclosure presents a novel package outline design that avoids the disadvantages resulting from these thinning or grinding procedures, i.e. lower CTI and violation of the design rules given by the IEC60664 standard if no safety margin is provided to compensate a lower CTI after mechanical treatment.

According to a first aspect, embodiments of the disclosure relate to a semiconductor package, comprising: a first substrate comprising a first upper main face and a second lower main face; a semiconductor chip comprising a first upper main face and a second lower main face, the second lower main face of the semiconductor chip disposed on the first upper main face of the first substrate; a leadframe comprising at least one lead, wherein the at least one lead is disposed on a side of the package and the at least one lead is electrically connected with the semiconductor chip; and an encapsulant applied to the first substrate, the semiconductor chip and the leadframe, the encapsulant comprising a first upper main face and a second lower main face, wherein the second lower main face of the encapsulant comprises a first portion extending in a first plane, a second portion extending in a second plane, a third portion extending in a first transition zone between the first plane and the second plane, and a fourth portion extending in a second transition zone between the second plane and the at least one lead, wherein the first portion of the second lower main face of the encapsulant and the second lower main face of the first substrate are extending in the same first plane, the first plane forming a lower heat dissipation surface of the package, wherein the second portion, the third portion and the fourth portion of the second lower main face of the encapsulant are dimensioned to keep a first predefined minimum distance between the first portion of the second lower main face of the encapsulant and the at least one lead.

The technical advantage of such a semiconductor package is that due to the first portion of the encapsulant extending in the first plane and the second portion of the encapsulant extending in the second plane, the surface insulation behavior of the package is independent of surface modification steps such as grinding or other thinning techniques applied to the first portion but not to the second portion of the encapsulant.

In an exemplary implementation of the semiconductor package, the first predefined minimum distance is a specified minimum insulation distance between the first portion of the second lower main face of the encapsulant and the at least one lead.

This provides the advantage that the first predefined minimum distance can be predetermined during a design phase of the semiconductor chip. Due to the dimensioning of the encapsulant, i.e. the second portion, the third portion and the fourth portion of the second lower main face of the encapsulant, the surface insulation areas of the power package are separated into two areas, the above mentioned first portion of the encapsulant and the above mentioned second portion of the encapsulant 130. The first one, i.e. the first portion, will see physical or other changes after molding and the second one, i.e. the second portion will stay unaffected. For the second area being unaffected, i.e. the second portion of the encapsulant, the specified minimum insulation distance can be guaranteed as this second area will see no changes during mechanical treatment.

In an exemplary implementation of the semiconductor package, the first predefined minimum distance is based on a specified electrical creepage distance between the first portion of the second lower main face of the encapsulant and the at least one lead.

This provides the advantage that due to the special design of the encapsulant described above with the first portion and the second portion of the encapsulant being arranged on two different planes that are horizontal with respect to each other, mechanical treatment will only affect the first portion of the encapsulant while the second portion of the encapsulant will stay unaffected. This special design of the encapsulant guarantees that the specified electrical creepage distance can be maintained.

In an exemplary implementation of the semiconductor package, the first predefined minimum distance is based on a given voltage, a pollution degree and a material of the encapsulant.

This provides the advantage that due to the special design of the encapsulant described above, a milling head is not in contact with the lower old body of the encapsulant as defined by the second portion. Hence there is no risk of smearing Cu particles in to the mold compound, i.e. the encapsulant; there is no change of insulation robustness of mold compound, e.g. with respect to CTI, and there is no impact on insulation length. The first predefined minimum distance can be maintained as originally specified based on a given voltage, a pollution degree and a material of the encapsulant.

In an exemplary implementation of the semiconductor package, the first predefined minimum distance is defined according to the Specification IEC 60664 specifying dimensioning of electrical creepage distances of functional insulation.

This provides the advantage that due to the novel package outline design the desired surface insulation behavior can be ensured also in case that the package needs to undergo mechanical treatment after molding, e.g. to increase flatness of the integrated heat spreader. This novel package outline design ensures that on both sides of the package, e.g. for DSC package, or on one side of the package, e.g. for SSC package, the integrated heat sinks to be flattened are elevated towards the remaining package body. This ensures that only the area to be treated will see changes in surface structure which will likely end up in lower surface isolation robustness. The area which is not affected by the mechanical treatment will fulfil the requirements of IEC 60664 standard.

In an exemplary implementation of the semiconductor package, the first predefined minimum distance is based on a given surface quality of the encapsulant.

This provides the advantage that the surface quality of the encapsulant which is known during the design of the package can be used to define the first predefined minimum distance. The first predefined minimum distance needs not to be designed based on the mechanical treatment process, e.g. by applying some tolerances with respect to this distance. Tolerances in the design of the package can be kept low.

In an exemplary implementation of the semiconductor package, the first portion of the second lower main face of the encapsulant is completely surrounded by the second portion of the second lower main face of the encapsulant.

This provides the advantage that milling or thinning can be applied from all four sides of the package without affecting the surface quality of the second portion of the encapsulant.

In an exemplary implementation of the semiconductor package, the first transition zone between the first plane and the second plane comprises a step-profile or a staircase profile or a ramp profile.

This provides the advantage that the milling head is in distance to the second portion of the encapsulant and cannot pollute the second portion based on which the creepage distance may be defined.

In an exemplary implementation of the semiconductor package, the second transition zone between the second plane and the at least one lead comprises a ramp-profile.

This provides the advantage that this profile of the second transition zone also contributes to specify the minimum distance, e.g. the creepage distance.

In an exemplary implementation of the semiconductor package, the semiconductor package comprises: an electrically conductive spacer layer comprising a first upper main face and a second lower main face, the first lower main face of the spacer layer being disposed on the first upper main face of the semiconductor chip; and a second substrate comprising a first upper main face and a second lower main face, the second lower main face of the second substrate being disposed on the first upper main face of the spacer layer; wherein the first upper main face of the encapsulant comprises a first portion extending in a fourth plane, a second portion extending in a third plane, a third portion extending in a first transition zone between the fourth plane and the third plane, and a fourth portion extending in a second transition zone between the third plane and the at least one lead, wherein the first portion of the first upper main face of the encapsulant and the first upper main face of the second substrate are extending in the same fourth plane, the fourth plane forming an upper heat dissipation surface of the package, wherein the second portion, the third portion and the fourth portion of the first upper main face of the encapsulant are dimensioned to keep a second predefined minimum distance between the first portion of the first upper main face of the encapsulant and the at least one lead.

The technical advantage of such a semiconductor package that may be formed as a DSC package is that due to the first portion of the encapsulant extending in the fourth plane and the second portion of the encapsulant extending in the third plane, the surface insulation behavior of the first upper main face of the encapsulant is independent of surface modification steps such as grinding or other thinning techniques applied to the first portion but not to the second portion of the encapsulant.

Both surfaces of the package may be mechanically treated without affecting the surface structure of the untreated area that is used for defining the creepage distances.

In an exemplary implementation of the semiconductor package, the second predefined minimum distance is a specified minimum insulation distance between the first portion of the first upper main face of the encapsulant and the at least one lead.

This provides the same advantages described above for the second lower main face of the encapsulant also for the first upper main face of the encapsulant. I.e. the second predefined minimum distance can be predetermined during a design phase of the semiconductor chip. Due to the dimensioning of the encapsulant, i.e. the second portion, the third portion and the fourth portion of the first upper main face of the encapsulant, the surface insulation areas of the power package are separated into two areas, the above mentioned first portion of the encapsulant and the above mentioned second portion of the encapsulant. The first one, i.e. the first portion, will see physical or other changes after molding and the second one, i.e. the second portion will stay unaffected. For the second area being unaffected, i.e. the second portion of the encapsulant, the specified minimum insulation distance can be guaranteed as this second area will see no changes during mechanical treatment.

In an exemplary implementation of the semiconductor package, the second predefined minimum distance is based on a specified electrical creepage distance between the first portion of the first upper main face of the encapsulant and the at least one lead.

This provides the same advantages described above for the second lower main face of the encapsulant also for the first upper main face of the encapsulant.

In an exemplary implementation of the semiconductor package, the second predefined minimum distance is based on a given voltage, a pollution degree and a material of the encapsulant.

This provides the same advantages described above for the second lower main face of the encapsulant also for the first upper main face of the encapsulant.

In an exemplary implementation of the semiconductor package, the second predefined minimum distance is defined according to the Specification IEC 60664 specifying dimensioning of electrical creepage distances of functional insulation.

This provides the same advantages described above for the second lower main face of the encapsulant also for the first upper main face of the encapsulant.

In an exemplary implementation of the semiconductor package, the second predefined minimum distance is based on a given surface quality of the encapsulant.

This provides the same advantages described above for the second lower main face of the encapsulant also for the first upper main face of the encapsulant.

In an exemplary implementation of the semiconductor package, the first portion, the second portion, the third portion and the fourth portion of the first upper main face of the encapsulant are symmetrically arranged with the first portion, the second portion, the third portion and the fourth portion of the second lower main face of the encapsulant.

This provides the advantage that mechanical treatment of the first upper main face of the encapsulant may correspond to mechanical treatment of the second lower main face of the encapsulant. For example, the same mechanical treatment process can be used when turning the semiconductor package upside down.

In an exemplary implementation of the semiconductor package, the semiconductor chip comprises one of a Silicon Carbide power transistor, a Silicon power transistor, a Gallium Nitride power transistor.

This provides the advantage that this package can be used for different semiconductor packages with different transistor structures.

The power transistor may be an IGBT or a MOSFET, for example.

In an exemplary implementation of the semiconductor package, the semiconductor chip comprises a power transistor designed for automotive applications.

This provides the advantage that this package can be advantageously applied for automotive applications.

In an exemplary implementation of the semiconductor package, the first substrate comprises an insulator layer, a first metallic layer disposed on a first upper main face of the insulator layer, and a second metallic layer disposed on a second lower main face of the insulator layer, wherein the second lower main face of the first substrate corresponds to a second lower main face of the second metallic layer of the first substrate.

This provides the advantage that robust substrates can be efficiently applied.

In an exemplary implementation of the semiconductor package, the first substrate comprises at least one of a Copper alloy, a Copper composite, an Aluminum alloy, an Aluminum composite.

This provides the advantage that these substrates are robust and may be advantageously used to design different metallization structures, e.g. connecting the leads.

According to a second aspect, embodiments of the present disclosure relate to a method for producing a semiconductor package, the method comprising: providing a first substrate comprising a first upper main face and a second lower main face; disposing a semiconductor chip on the first substrate, the semiconductor chip comprising a first upper main face and a second lower main face, wherein the second lower main face of the semiconductor chip is disposed on the first upper main face of the first substrate; electrically connecting a leadframe with the semiconductor chip, the leadframe comprising at least one lead disposed on a side of the package, the at least one lead being electrically connected with the semiconductor chip; and applying an encapsulant to the first substrate, the semiconductor chip and the leadframe, the encapsulant comprising a first upper main face and a second lower main face, wherein the second lower main face of the encapsulant comprises a first portion extending in a first plane, a second portion extending in a second plane, a third portion extending in a first transition zone between the first plane and the second plane, and a fourth portion extending in a second transition zone between the second plane and the at least one lead, wherein the first portion of the second lower main face of the encapsulant and the second lower main face of the first substrate are extending in the same first plane, the first plane forming a lower heat dissipation surface of the package, wherein the second portion, the third portion and the fourth portion of the second lower main face of the encapsulant are dimensioned to keep a predefined minimum distance between the first portion of the second lower main face of the encapsulant and the at least one lead.

The technical advantage of such a method is that due to the first portion of the encapsulant extending in the first plane and the second portion of the encapsulant extending in the second plane, the surface insulation behavior of a package produced by such method is independent of surface modification steps such as grinding or other thinning techniques applied to the first portion but not to the second portion of the encapsulant.

### BRIEF DESCRIPTION OF THE DRAWINGS

Further embodiments of the present disclosure will be described with respect to the following figures, in which:

FIGS. 1a and 1b show a sectional view 100a and a top view 100b of a semiconductor package 100 according to an embodiment;

FIG. 2 shows a top view 200a, a lateral view 200b and a bottom view 200c of a semiconductor package 100 according to an embodiment;

FIG. 3 shows a lateral view 300a, 300b of a semiconductor package 100 according to an embodiment before mechanical treatment 300a and after mechanical treatment 300b;

FIG. 4 shows a sectional view of a semiconductor package 400 according to an embodiment;

FIG. 5 shows a top side representation 500a and a bottom side representation 500b of a semiconductor package 100 according to an embodiment; and

FIG. 6 shows a schematic diagram illustrating a method 600 for producing a semiconductor package according to an embodiment.

### DETAILED DESCRIPTION

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the present disclosure.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

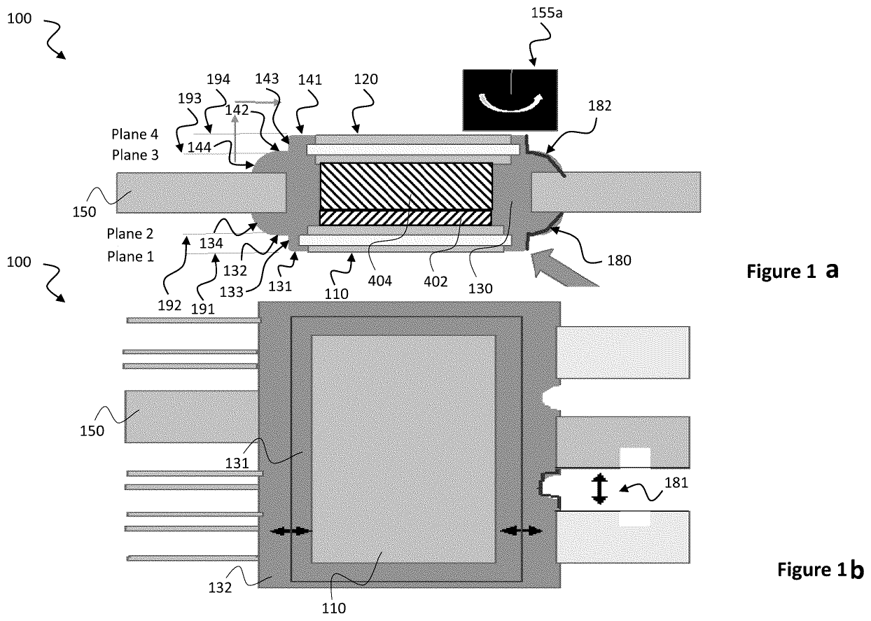

FIGS. 1a and 1b show a sectional view 100a and a top view 100b of a semiconductor package 100 according to an embodiment.

The semiconductor package 100 comprises a first substrate 110 which comprises a first upper main face and a second lower main face.

The semiconductor package 100 comprises a semiconductor chip 402 comprising a first upper main face and a second lower main face. The second lower main face of the semiconductor chip 402 is disposed on the first upper main face of the first substrate 110.

The semiconductor package 100 comprises a leadframe comprising at least one lead 150. The at least one lead 150 is disposed on a side of the package 100. The at least one lead 150 is electrically connected with the semiconductor chip 402 (not shown in FIG. 1).

The semiconductor package 100 comprises an encapsulant 130 applied to the first substrate 110, the semiconductor chip 402 and the leadframe. The encapsulant 130 comprises a first upper main face and a second lower main face.

The second lower main face of the encapsulant 130 comprises a first portion 131 extending in a first plane 191, a second portion 132 extending in a second plane 192, a third portion 133 extending in a first transition zone between the first plane 191 and the second plane 192, and a fourth portion 134 extending in a second transition zone between the second plane 192 and the at least one lead 150.

The first portion 131 of the second lower main face of the encapsulant 130 and the second lower main face of the first substrate 110 are extending in the same first plane 191 which first plane 191 is forming a lower heat dissipation surface of the package 100.

The second portion 132, the third portion 133 and the fourth portion 134 of the second lower main face of the encapsulant 130 are dimensioned to keep a first predefined minimum distance 180 between the first portion 131 of the second lower main face of the encapsulant 130 and the at least one lead 150.

The first predefined minimum distance 180 may be a specified minimum insulation distance between the first portion 131 of the second lower main face of the encapsulant 130 and the at least one lead 150.

The first predefined minimum distance 180 may be based on a specified electrical creepage distance between the first portion 131 of the second lower main face of the encapsulant 130 and the at least one lead 150.

The first predefined minimum distance 180 may be based on a given voltage, a pollution degree and a material of the encapsulant 130.

The first predefined minimum distance 180 may be defined according to the Specification IEC 60664, in particular according to Table F.4 of the IEC 60664 standard shown above, specifying dimensioning of electrical creepage distances of functional insulation.

The first predefined minimum distance 180 may be based on a given surface quality of the encapsulant 130.

The first portion 131 of the second lower main face of the encapsulant 130 may be completely surrounded by the second portion 132 of the second lower main face of the encapsulant 130.

The first transition zone between the first plane 191 and the second plane 192 may comprise a step-profile or a staircase profile or a ramp profile.

The second transition zone between the second plane 192 and the at least one lead 150 may comprise a ramp-profile.

The semiconductor package 100 may further comprise an electrically conductive spacer layer 404 comprising a first upper main face and a second lower main face. The first lower main face of the spacer layer 404 may be disposed on the first upper main face of the semiconductor chip 402.

The semiconductor package 100 may further comprise a second substrate 120 comprising a first upper main face and a second lower main face. The second lower main face of the second substrate may be disposed on the first upper main face of the spacer layer 404.

The first upper main face of the encapsulant 130 may comprise a first portion 141 extending in a fourth plane 194, a second portion 142 extending in a third plane 193, a third portion 143 extending in a first transition zone between the fourth plane 194 and the third plane 193, and a fourth portion 144 extending in a second transition zone between the third plane 193 and the at least one lead 150.

The first portion 141 of the first upper main face of the encapsulant 130 and the first upper main face of the second substrate 120 may extend in the same fourth plane 194 which fourth plane 194 is forming an upper heat dissipation surface of the package 100.

The second portion 142, the third portion 143 and the fourth portion 144 of the first upper main face of the encapsulant 130 may be dimensioned to keep a second predefined minimum distance 182 between the first portion 141 of the first upper main face of the encapsulant 130 and the at least one lead 150.

The second predefined minimum distance 182 may be a specified minimum insulation distance between the first portion 141 of the first upper main face of the encapsulant 130 and the at least one lead 150.

The second predefined minimum distance 182 may be based on a specified electrical creepage distance between the first portion 141 of the first upper main face of the encapsulant 130 and the at least one lead 150.

The second predefined minimum distance 182 may be based on a given voltage, a pollution degree and a material of the encapsulant 130.

The second predefined minimum distance 182 may be defined according to the Specification IEC 60664 specifying dimensioning of electrical creepage distances of functional insulation, e.g. as shown above with respect to Table F.4 of the IEC 60664 standard.

The second predefined minimum distance 182 may be based on a given surface quality of the encapsulant 130.

The first portion, the second portion, the third portion and the fourth portion of the first upper main face of the encapsulant may be symmetrically arranged with the first portion, the second portion, the third portion and the fourth portion of the second lower main face of the encapsulant.

The semiconductor chip 402 may comprise one of a Silicon Carbide power transistor, a Silicon power transistor, a Gallium Nitride power transistor.

The semiconductor chip 402 may comprise a power transistor designed for automotive applications.

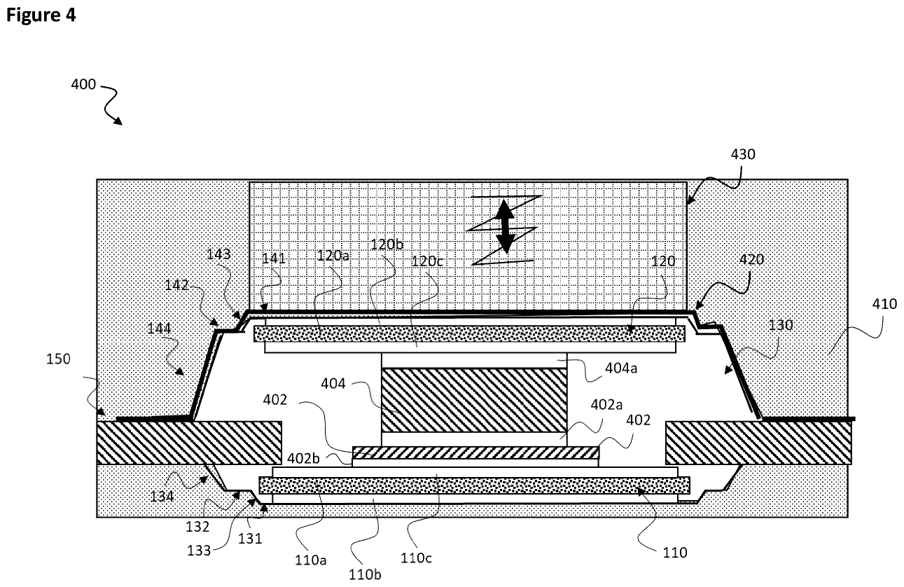

The first substrate 110 may comprise an insulator layer 110a, a first metallic layer 110c disposed on a first upper main face of the insulator layer 110a, and a second metallic layer 110b disposed on a second lower main face of the insulator layer 110a, e.g. as shown in FIG. 4. The second lower main face of the first substrate 110 may correspond to a second lower main face of the second metallic layer 110b of the first substrate 110.

The first substrate 110 may comprise at least one of a Copper alloy, a Copper composite, an Aluminum alloy, an Aluminum composite.

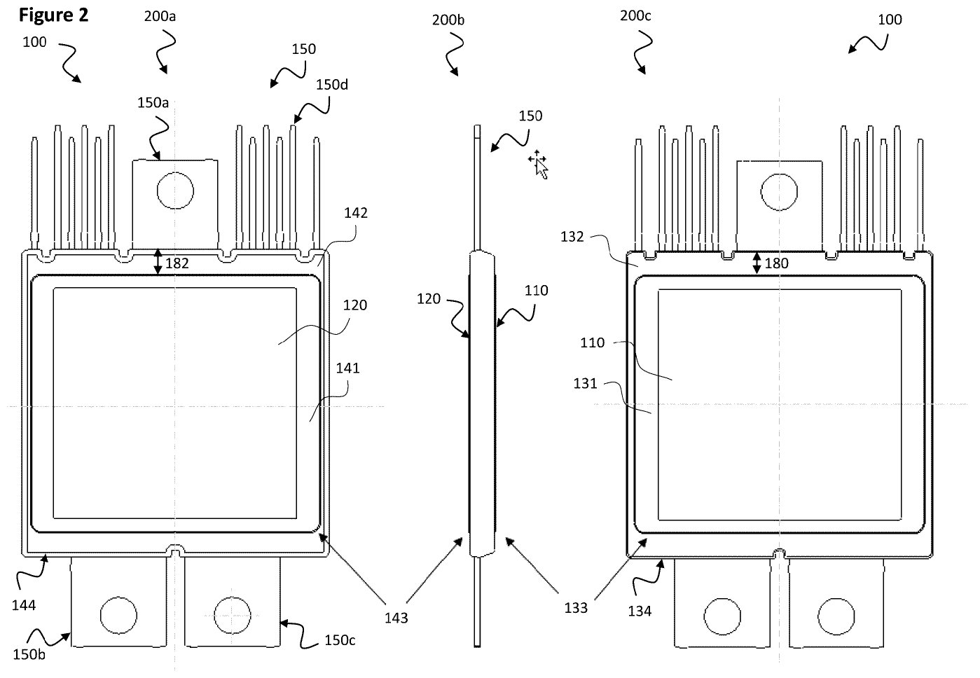

FIG. 2 shows a top view 200a, a lateral view 200b and a bottom view 200c of a semiconductor package 100 according to an embodiment.

The figure shows an example of double side cooling package outline. In this semiconductor package example, an insulation length of untreated area is minimum 4.6 mm, where the bottom side 200c of the package 100 is used as reference. For a voltage class of 800 V, a CTI of 600 and a pollution degree of 2, a minimum of 4 mm creepage distance may be needed.

The semiconductor package 100 corresponds to the semiconductor package 100 described above with respect to FIG. 1.

In this example, leads 150 may be arranged on two sides of the package 100. A first main lead 150a, e.g. an AC contact, and several further leads 150d, e.g. for connection of control terminals of the semiconductor chip, are arranged on one side of the package 100 while a second main lead 150b and a third main lead 150c, e.g. for connection of DC contacts, are arranged on the opposite side of the package 100.

In other implementations of the package 100, leads 150 may be placed only on a single side of the package or leads 150 may be placed on three sides or even on all four sides of the package 100.

The bottom view 200c of the semiconductor package 100 shows the second lower main face of the encapsulant 130.

The second lower main face of the encapsulant 130 comprises the first portion 131 extending in a first plane 191 as described above with respect to FIG. 1, the second portion 132 extending in a second plane 192 as described above with respect to FIG. 1, a third portion 133 extending in a first transition zone between the first plane 191 and the second plane 192, and a fourth portion 134 extending in a second transition zone between the second plane 192 and the at least one lead 150.

The first portion 131 of the second lower main face of the encapsulant 130 and the second lower main face of the first substrate 110 are extending in the same first plane 191 which first plane 191 is forming a lower heat dissipation surface of the package 100 as described above with respect to FIG. 1.

The second portion 132, the third portion 133 and the fourth portion 134 of the second lower main face of the encapsulant 130 are dimensioned to keep a first predefined minimum distance 180 between the first portion 131 of the second lower main face of the encapsulant 130 and the at least one lead 150 as described above with respect to FIG. 1.

In this implementation of the semiconductor package shown in FIG. 2, the third portion 133 of the encapsulant comprises a step-like profile such that the first portion 131 of the encapsulant 130 is forming a plateau or also referred to as “pedestal” on the second portion 132 of the encapsulant 130. This plateau or pedestal provides the advantage that mechanical treatment 155a, e.g. by grinding or thinning can only be performed on the first portion 131 of the second lower main face of the encapsulant 130 and the second lower main face of the first substrate 110, i.e. the lower heat dissipation surface of the package 100, without affecting the second portion 132 of the encapsulant 130. That means, no pollution of the second portion 132 of the encapsulant 130, e.g. by Cu smearing or change of surface properties of this second portion 132 can take place. A dimensioning of the second portions 132 of the encapsulant with respect to the first predefined minimum distance 180 will not be negatively affected.

The surface insulation areas of the power package 100 are separated into two areas, the above mentioned first portion 131 of the encapsulant 130 and the above mentioned second portion 132 of the encapsulant 130. The first one, i.e. the first portion 131, will see physical or other changes after molding and the second one, i.e. the second portion 132 will stay unaffected. For the second area being unaffected, i.e. the second portion 132 of the encapsulant 130, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package 100.

The top view 200a of the semiconductor package 100 shows the first upper main face of the encapsulant 130.

The first upper main face of the encapsulant 130 comprises a first portion 141 extending in a fourth plane 194 as described above with respect to FIG. 1, a second portion 142 extending in a third plane 193 as described above with respect to FIG. 1, a third portion 143 extending in a first transition zone between the fourth plane 194 and the third plane 193, and a fourth portion 144 extending in a second transition zone between the third plane 193 and the at least one lead 150.

The first portion 141 of the first upper main face of the encapsulant 130 and the first upper main face of the second substrate 120 are extending in the same fourth plane 194 which fourth plane 194 is forming an upper heat dissipation surface of the package 100 as described above with respect to FIG. 1.

The second portion 142, the third portion 143 and the fourth portion 144 of the first upper main face of the encapsulant 130 are dimensioned to keep a second predefined minimum distance 182 between the first portion 141 of the first upper main face of the encapsulant 130 and the at least one lead 150 as described above with respect to FIG. 1.

In this implementation of the semiconductor package shown in FIG. 2, the same advantages described above for the second lower main face of the encapsulant 130 with respect to the bottom view 200c also hold for the first upper main face of the encapsulant 130, i.e. with respect to the top view 200a. That means, the third portion 143 of the first upper main face of the encapsulant 130 comprises a step-like profile such that the first portion 141 of the encapsulant 130 is forming a plateau or also referred to as “pedestal” on the second portion 142 of the first upper main face of the encapsulant 130. This plateau or pedestal provides the advantage that mechanical treatment 155a, e.g. by grinding or thinning on the first upper main face of the encapsulant 130 can only be performed on the first portion 141 of the first upper main face of the encapsulant 130 and the first upper main face of the second substrate 120, i.e. the upper heat dissipation surface of the package 100, without affecting the second portion 142 of first upper main face of the encapsulant 130. That means, no pollution of the second portion 142 of the encapsulant 130, e.g. by Cu smearing or change of surface properties of this second portion 142 can take place. A dimensioning of the second portion 142 of the encapsulant with respect to the second predefined minimum distance 182 will not be negatively affected.

The surface insulation areas of the power package 100 are separated into two areas, the above mentioned first portion 141 of the first upper main face of the encapsulant 130 and the above mentioned second portion 142 of the first upper main face of the encapsulant 130. The first one, i.e. the first portion 141, will see physical or other changes after molding and the second one, i.e. the second portion 142 will stay unaffected. For the second area being unaffected, i.e. the second portion 142 of the encapsulant 130, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package 100.

Therefore, the semiconductor package 100 represents a novel package outline design which ensures desired surface insulation behavior in case that the package 100 needs to undergo mechanical treatment after molding, e.g. to increase flatness of the integrated heat spreader. This novel package outline design ensures that on both sides, e.g. for DSC package 100 shown here in FIG. 2 (but also on only one side, e.g. for SSC package) of the package 100 the integrated heat sinks to be flattened are elevated towards the remaining package body.

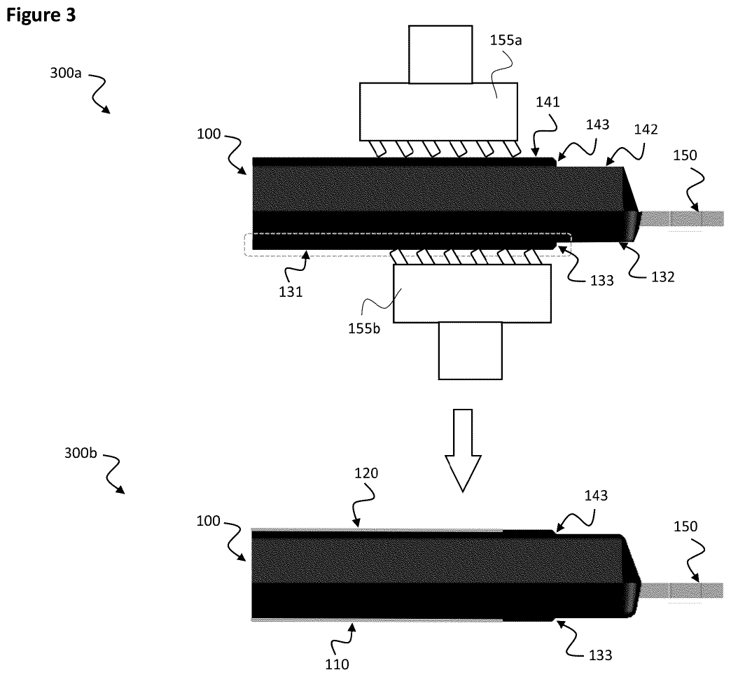

FIG. 3 shows a lateral view 300a, 300b of a semiconductor package 100 according to an embodiment before mechanical treatment 300a and after mechanical treatment 300b.

The semiconductor package 100 corresponds to the semiconductor package 100 described above with respect to FIG. 1.

The surface insulation areas of the power package 100 are separated into two areas, the above mentioned first portion 131 of the lower main face of the encapsulant 130 and the above mentioned second portion 132 of the lower main face of the encapsulant 130. The first one, i.e. the first portion 131, will see physical or other changes after molding and the second one, i.e. the second portion 132 will stay unaffected. For the second area being unaffected, i.e. the second portion 132 of the lower main face of the encapsulant 130, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package 100.

The same properties also hold for the first upper main face of the encapsulant 130 as shown in the following. The surface insulation areas of the power package 100 are separated into two areas, the above mentioned first portion 141 of the first upper main face of the encapsulant 130 and the above mentioned second portion 142 of the first upper main face of the encapsulant 130. The first one, i.e. the first portion 141, will see physical or other changes after molding and the second one, i.e. the second portion 142 will stay unaffected. For the second area being unaffected, i.e. the second portion 142 of the encapsulant 130, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package 100.

Therefore, the semiconductor package 100 represents a novel package outline design which ensures desired surface insulation behavior in case that the package 100 needs to undergo mechanical treatment after molding, e.g. to increase flatness of the integrated heat spreader. This novel package outline design ensures that on both sides, e.g. for DSC package 100 shown here in FIG. 3 (but also on only one side, e.g. for SSC package) of the package 100 the integrated heat sinks to be flattened are elevated towards the remaining package body.

In this implementation of the semiconductor package shown in FIG. 3, the third portion 133 of the second lower main face of the encapsulant comprises a step-like profile such that the first portion 131 of the encapsulant 130 is forming a plateau or also referred to as “pedestal” on the second portion 132 of the encapsulant 130. This plateau or pedestal provides the advantage that mechanical treatment 155a, e.g. by grinding or thinning can only be performed on the first portion 131 of the second lower main face of the encapsulant 130 and the second lower main face of the first substrate 110, i.e. the lower heat dissipation surface of the package 100, without affecting the second portion 132 of the encapsulant 130. That means, no pollution of the second portion 132 of the encapsulant 130, e.g. by Cu smearing or change of surface properties of this second portion 132 can take place. A dimensioning of the second portions 132 of the encapsulant with respect to the first predefined minimum distance 180 will not be negatively affected.

In this implementation of the semiconductor package shown in FIG. 3, the same advantages described above for the second lower main face of the encapsulant 130 also hold for the first upper main face of the encapsulant 130. That means, the third portion 143 of the first upper main face of the encapsulant 130 comprises a step-like profile such that the first portion 141 of the encapsulant 130 is forming a plateau or also referred to as “pedestal” on the second portion 142 of the first upper main face of the encapsulant 130. This plateau or pedestal provides the advantage that mechanical treatment 155a, e.g. by grinding or thinning on the first upper main face of the encapsulant 130 can only be performed on the first portion 141 of the first upper main face of the encapsulant 130 and the first upper main face of the second substrate 120, i.e. the upper heat dissipation surface of the package 100, without affecting the second portion 142 of first upper main face of the encapsulant 130. That means, no pollution of the second portion 142 of the encapsulant 130, e.g. by Cu smearing or change of surface properties of this second portion 142 can take place. A dimensioning of the second portion 142 of the encapsulant with respect to the second predefined minimum distance 182 will not be negatively affected.

FIG. 4 shows a sectional view of a semiconductor package 400 according to an embodiment.

The semiconductor package 400 may correspond to the semiconductor package 100 described above with respect to FIGS. 1 to 3. In this sectional view a design of the internal layers of the semiconductor package is illustrated.

The semiconductor package 400 comprises a first substrate 110 which comprises a first upper main face and a second lower main face.

The first substrate 110 comprises an insulator layer 110a, a first metallic layer 110c disposed on a first upper main face of the insulator layer 110a, and a second metallic layer 110b disposed on a second lower main face of the insulator layer 110a. The second lower main face of the first substrate 110 corresponds to the second lower main face of the second metallic layer 110b of the first substrate 110.

The semiconductor package 400 comprises a semiconductor chip 402 comprising a first upper main face and a second lower main face. The second lower main face of the semiconductor chip 402 is disposed on the first upper main face of the first substrate 110.

The semiconductor chip 402 comprises a first metallization layer 402a disposed on its first upper main face and a second metallization layer 402b disposed on its second lower main face. The second metallization layer 402b of the semiconductor chip 402 is disposed on the first metallic layer 110c of the first substrate 110.

The semiconductor package 400 further comprises an electrically conductive spacer layer 404 comprising a first upper main face and a second lower main face. The first lower main face of the spacer layer 404 is disposed on the first metallization layer 402a of the semiconductor chip 402, i.e. on the first upper main face of the semiconductor chip 402.

The electrically conductive spacer layer 404 comprises a metallization layer 404a disposed on its first upper main face.

The semiconductor package 400 further comprises a second substrate 120 comprising a first upper main face and a second lower main face. The second lower main face of the second substrate is disposed on the metallization layer 404a of the spacer layer 404, i.e. on the first upper main face of the spacer layer 404.

The second substrate 120 comprises an insulator layer 120a, a first metallic layer 120b disposed on a first upper main face of the insulator layer 120a, and a second metallic layer 120c disposed on a second lower main face of the insulator layer 120a. The first upper main face of the second substrate 120 corresponds to the first upper main face of the first metallic layer 120b of the second substrate 120.

The semiconductor package 400 comprises a leadframe comprising at least one lead 150. The at least one lead 150 is disposed on a side of the package 400. The at least one lead 150 is electrically connected with the semiconductor chip 402 (not shown in FIG. 4).

The semiconductor package 400 comprises an encapsulant 130 applied to the first substrate 110, the second substrate 120, the semiconductor chip 402 and the leadframe. The encapsulant 130 comprises a first upper main face and a second lower main face.

As described above with respect to the semiconductor package 100 shown in FIGS. 1 to 3, the second lower main face of the encapsulant 130 comprises a first portion 131 extending in a first plane 191 as shown in FIG. 1, a second portion 132 extending in a second plane 192 as shown in FIG. 1, a third portion 133 extending in a first transition zone between the first plane 191 and the second plane 192, and a fourth portion 134 extending in a second transition zone between the second plane 192 and the at least one lead 150.

The first portion 131 of the second lower main face of the encapsulant 130 and the second lower main face of the first substrate 110 are extending in the same first plane 191 which first plane 191 is forming a lower heat dissipation surface of the package 100.

The second portion 132, the third portion 133 and the fourth portion 134 of the second lower main face of the encapsulant 130 are dimensioned to keep a first predefined minimum distance 180 as shown in FIG. 1 between the first portion 131 of the second lower main face of the encapsulant 130 and the at least one lead 150.

The first predefined minimum distance 180 may be a specified minimum insulation distance between the first portion 131 of the second lower main face of the encapsulant 130 and the at least one lead 150.

As described above with respect to FIGS. 1 to 3, the first predefined minimum distance 180 may be based on a specified electrical creepage distance between the first portion 131 of the second lower main face of the encapsulant 130 and the at least one lead 150. The first predefined minimum distance 180 may be based on a given voltage, a pollution degree and a material of the encapsulant 130. The first predefined minimum distance 180 may be defined according to the Specification IEC 60664, in particular according to Table F.4 of the IEC 60664 standard shown above, specifying dimensioning of electrical creepage distances of functional insulation. The first predefined minimum distance 180 may be based on a given surface quality of the encapsulant 130.

As described above with respect to FIGS. 1 to 3, the first upper main face of the encapsulant 130 comprises a first portion 141 extending in a fourth plane 194 as shown in FIG. 1, a second portion 142 extending in a third plane 193 as shown in FIG. 1, a third portion 143 extending in a first transition zone between the fourth plane 194 and the third plane 193, and a fourth portion 144 extending in a second transition zone between the third plane 193 and the at least one lead 150.

The first portion 141 of the first upper main face of the encapsulant 130 and the first upper main face of the second substrate 120 may extend in the same fourth plane 194 which fourth plane 194 is forming an upper heat dissipation surface of the package 100 as described above with respect to FIGS. 1 to 3.

The second portion 142, the third portion 143 and the fourth portion 144 of the first upper main face of the encapsulant 130 may be dimensioned to keep a second predefined minimum distance 182 between the first portion 141 of the first upper main face of the encapsulant 130 and the at least one lead 150 as described above with respect to FIGS. 1 to 3.

The second predefined minimum distance 182 may be a specified minimum insulation distance between the first portion 141 of the first upper main face of the encapsulant 130 and the at least one lead 150 as described above with respect to FIGS. 1 to 3.

As described above, both substrates 110, 120 may comprise an insulator layer 110a, 120a covered with metallic layers 110b, 110c, 120b, 120c on both of its main surfaces. The insulator layer 110a, 120a may comprise a ceramic material. The substrate can for example be a direct copper bonded (DCB) substrate, a direct aluminum bonded (DAB) substrate or an active metal brazing (AMB) substrate. The substrate can also be an insulated metal substrate (IMS).

As described above, the semiconductor chip 402 may comprise metallization layers 402a, 402b on both of its main surfaces. The semiconductor chip 402 may comprise a transistor, e.g. a MOSFET transistor structure or an IGBT (insulated gate bipolar transistor) structure. These transistor structures may be provided such that at least one electrical contact element is arranged on a first main face of the semiconductor die and at least one other electrical contact element is arranged on a second main face opposite to the first main face of the semiconductor die, i.e. vertical transistor structures.

The electrically conductive spacer layer 404 may be fabricated of Cu, a Cu alloy or a Cu refractory material. The Cu refractory material may be a layer stack of alternating layers of copper and molybdenum, for example. The selection of the material of the spacer layer 404 may depend on requirements to achieve an optimal CTE match with the encapsulant 130. The thickness of the spacer layer 404 may be in a range from about 200 micrometers to about 1500 micrometer, depending on the thickness of the leads 150 of the leadframe.

In an optional implementation of the semiconductor package 400 a mold foil 420 is placed on the first upper main face of the encapsulant 130, in particular on the first portion 141, the second portion 142, the third portion 143 and the fourth portion 144 of the first upper main face of the encapsulant 130 and at least partially on the at least one lead 150 as illustrated in FIG. 4. A swivel 430, i.e. a spring-bearing compensation element, can optionally be arranged on the first upper main face of the encapsulant 130, in particular on the first portion 141 thereof. The swivel 430 can be used to provide a compensation for manufacturing tolerances. A mold tool 410 may be used to shape the encapsulant 130 in order to form the first portion 141, the second portion 142, the third portion 143 and the fourth portion 144 of the first upper main face of the encapsulant 130 as described above.

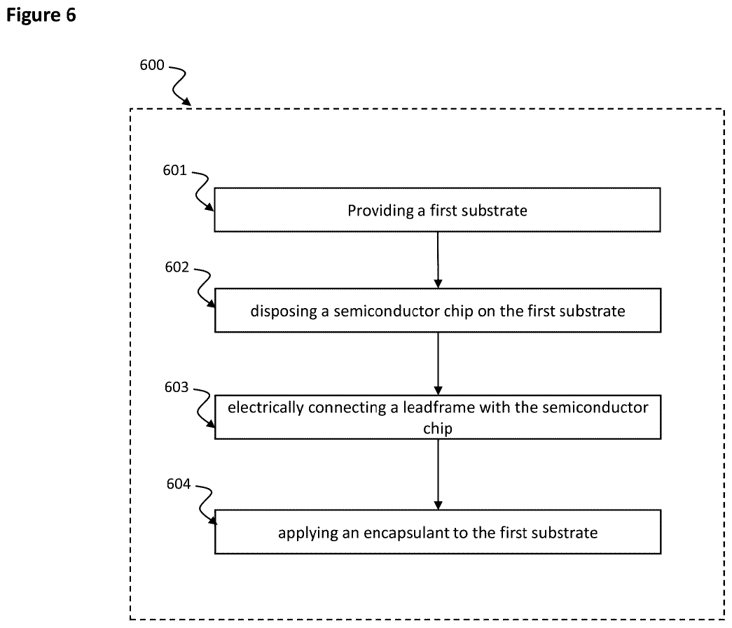

The semiconductor package 400 may be manufactured as described below with respect to FIG. 6.

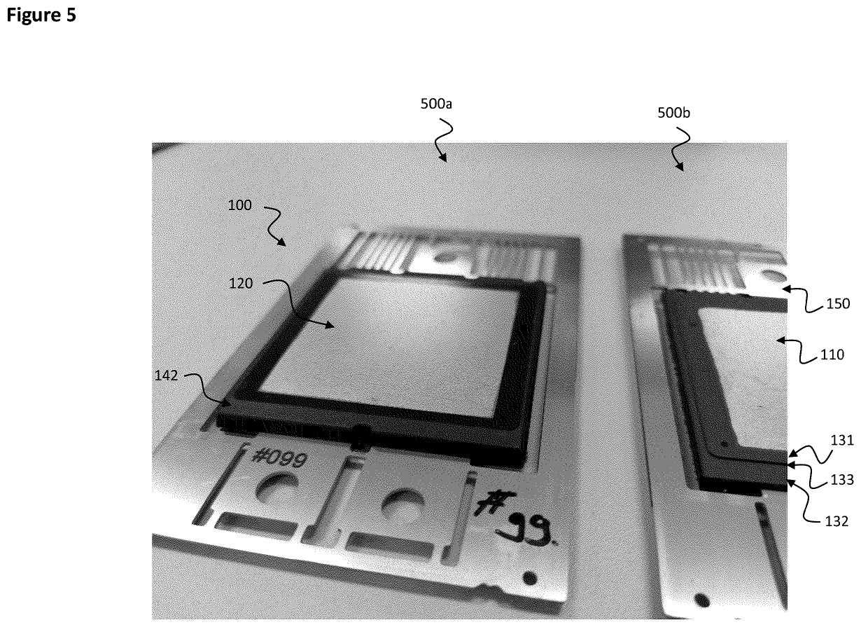

FIG. 5 shows a top side representation 500a and a bottom side representation 500b of a semiconductor package 100 according to an embodiment.

The semiconductor package 100 corresponds to the semiconductor package 100 described above with respect to FIGS. 1 to 3.

As described above with respect to FIGS. 1 to 3, the semiconductor package 100 comprises a first substrate 110, a second substrate 120, a semiconductor chip, a leadframe comprising at least one lead 150 and an encapsulant 130 applied to the first substrate 110, the second substrate 120, the semiconductor chip and the leadframe.

The surface insulation areas of the power package 100 are separated into two areas, the above mentioned first portion 131 of the lower main face of the encapsulant 130 and the above mentioned second portion 132 of the lower main face of the encapsulant 130 (see bottom side representation 500b). The first one, i.e. the first portion 131, will see physical or other changes after molding and the second one, i.e. the second portion 132 will stay unaffected. For the second area being unaffected, i.e. the second portion 132 of the lower main face of the encapsulant 130, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package 100.

The same properties also hold for the first upper main face of the encapsulant 130 as shown in the following. The surface insulation areas of the power package 100 are separated into two areas, the above mentioned first portion 141 of the first upper main face of the encapsulant 130 and the above mentioned second portion 142 of the first upper main face of the encapsulant 130 (see top side representation 500a). The first one, i.e. the first portion 141, will see physical or other changes after molding and the second one, i.e. the second portion 142 will stay unaffected. For the second area being unaffected, i.e. the second portion 142 of the encapsulant 130, the creepage insulating distance may be chosen according to the IEC60664 standard. This means that everything that is happening to the milled area of the mold body, such as smeared in Cu particles, change in CTI due to higher level of filler particles, etc., will not affect the isolation requirements of the power package 100.

FIG. 6 shows a schematic diagram illustrating a method 600 for producing a semiconductor package according to an embodiment.

The semiconductor package may correspond to the semiconductor package 100 described above with respect to FIGS. 1 to 3 and 5 or to the semiconductor package 400 described above with respect to FIG. 4.

The method 600 comprises providing 601 a first substrate 110 comprising a first upper main face and a second lower main face, e.g. as described above with respect to FIGS. 1 to 5.

The method 600 comprises disposing 602 a semiconductor chip 402 on the first substrate, the semiconductor chip comprising a first upper main face and a second lower main face, wherein the second lower main face of the semiconductor chip is disposed on the first upper main face of the first substrate, e.g. as described above with respect to FIGS. 1 to 5.

The method 600 comprises electrically connecting 603 a leadframe with the semiconductor chip, the leadframe comprising at least one lead 150 disposed on a side of the package, the at least one lead being electrically connected with the semiconductor chip, e.g. as described above with respect to FIGS. 1 to 5.

The method 600 comprises applying 604 an encapsulant 130 to the first substrate, the semiconductor chip and the leadframe, the encapsulant comprising a first upper main face and a second lower main face, e.g. as described above with respect to FIGS. 1 to 5, wherein the second lower main face of the encapsulant 130 comprises a first portion 131 extending in a first plane 191, a second portion 132 extending in a second plane 192, a third portion 133 extending in a first transition zone between the first plane 191 and the second plane 192, and a fourth portion 134 extending in a second transition zone between the second plane 192 and the at least one lead 150, wherein the first portion 131 of the second lower main face of the encapsulant 130 and the second lower main face of the first substrate 110 are extending in the same first plane 191, the first plane 191 forming a lower heat dissipation surface of the package 100, and wherein the second portion 132, the third portion 133 and the fourth portion 134 of the second lower main face of the encapsulant 130 are dimensioned to keep a predefined minimum distance 180 between the first portion 131 of the second lower main face of the encapsulant 130 and the at least one lead 150, e.g. as described above with respect to FIGS. 1 to 5.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the present disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the present disclosure beyond those described herein. While the present disclosure has been described with reference to one or more particular embodiments, those skilled in the art recognize that many changes may be made thereto without departing from the scope of the present disclosure. It is therefore to be understood that within the scope of the appended claims and their equivalents, the present disclosure may be practiced otherwise than as specifically described herein.

What is claimed is:

1. A semiconductor package, comprising:
a first substrate comprising a first upper main face and a second lower main face;
a semiconductor chip comprising a first upper main face and a second lower main face, the second lower main face of the semiconductor chip disposed on the first upper main face of the first substrate;
a leadframe comprising at least one lead, wherein the at least one lead is disposed on a side of the semiconductor package, and the at least one lead is electrically connected with the semiconductor chip; and
an encapsulant applied to the first substrate, the semiconductor chip and the leadframe, the encapsulant comprising a first upper main face and a second lower main face,
wherein the second lower main face of the encapsulant comprises a first portion extending in a first plane, a second portion extending in a second plane, a third portion extending in a first transition zone between the first plane and the second plane, and a fourth portion extending in a second transition zone between the second plane and the at least one lead,
wherein both the first portion of the second lower main face of the encapsulant and the second lower main face of the first substrate extend in the first plane, the first plane forming a lower heat dissipation surface of the semiconductor package,
wherein the second portion, the third portion and the fourth portion of the second lower main face of the encapsulant are dimensioned so as to keep a first predefined minimum distance between the first portion of the second lower main face of the encapsulant and the at least one lead.

2. The semiconductor package of claim 1,
wherein the first predefined minimum distance is a specified minimum insulation distance between the first portion of the second lower main face of the encapsulant and the at least one lead.

3. The semiconductor package of claim 1,
wherein the first predefined minimum distance is based on a specified electrical creepage distance between the first portion of the second lower main face of the encapsulant and the at least one lead.

4. The semiconductor package of claim 1,
wherein the first predefined minimum distance is based on a given voltage, a pollution degree and a material of the encapsulant.

5. The semiconductor package of claim 1,
wherein the first predefined minimum distance is defined according to the Specification IEC 60664 specifying dimensioning of electrical creepage distances of functional insulation.

6. The semiconductor package of claim 1,
wherein the first predefined minimum distance is based on a surface quality of the encapsulant.

7. The semiconductor package of claim 1,
wherein the first portion of the second lower main face of the encapsulant is completely surrounded by the second portion of the second lower main face of the encapsulant.

8. The semiconductor package of claim 1,
wherein the first transition zone between the first plane and the second plane comprises a step-profile, or a staircase profile, or a ramp profile.

9. The semiconductor package of claim 1,
wherein the second transition zone between the second plane and the at least one lead comprises a ramp-profile.

10. The semiconductor package of claim 1, further comprising:
an electrically conductive spacer layer comprising a first upper main face and a second lower main face, the first lower main face of the spacer layer being disposed on the first upper main face of the semiconductor chip; and
a second substrate comprising a first upper main face and a second lower main face, the second lower main face of the second substrate being disposed on the first upper main face of the spacer layer;
wherein the first upper main face of the encapsulant comprises a first portion extending in a fourth plane, a second portion extending in a third plane, a third portion extending in a third transition zone between the fourth plane and the third plane, and a fourth portion extending in a fourth transition zone between the third plane and the at least one lead,
wherein both the first portion of the first upper main face of the encapsulant and the first upper main face of the second substrate extend in the fourth plane, the fourth plane forming an upper heat dissipation surface of the semiconductor package,
wherein the second portion, the third portion and the fourth portion of the first upper main face of the encapsulant are dimensioned so as to keep a second predefined minimum distance between the first portion of the first upper main face of the encapsulant and the at least one lead.

11. The semiconductor package of claim 10,
wherein the second predefined minimum distance is a specified minimum insulation distance between the first portion of the first upper main face of the encapsulant and the at least one lead.

12. The semiconductor package of claim 10,
wherein the second predefined minimum distance is based on a specified electrical creepage distance between the first portion of the first upper main face of the encapsulant and the at least one lead.

13. The semiconductor package of claim 10,
wherein the second predefined minimum distance is based on a given voltage, a pollution degree and a material of the encapsulant.

14. The semiconductor package of claim 10,
wherein the second predefined minimum distance is defined according to the Specification IEC 60664 specifying dimensioning of electrical creepage distances of functional insulation.

15. The semiconductor package of claim 10,
wherein the second predefined minimum distance is based on a surface quality of the encapsulant.

16. The semiconductor package of claim 10,
wherein the first portion, the second portion, the third portion and the fourth portion of the first upper main face of the encapsulant are symmetrically arranged with the first portion, the second portion, the third portion and the fourth portion of the second lower main face of the encapsulant.

17. The semiconductor package of claim 1,
wherein the semiconductor chip comprises one of a silicon carbide power transistor, a silicon power transistor, or a gallium nitride power transistor.

18. The semiconductor package of claim 1,
wherein the semiconductor chip comprises a power transistor designed for automotive applications.

19. The semiconductor package of claim 1,
wherein the first substrate comprises:
an insulator layer having a first upper main face and a second lower main face,
a first metallic layer disposed on the first upper main face of the insulator layer, and
a second metallic layer disposed on the second lower main face of the insulator layer, the second metallic layer having a first upper main face and a second lower main face,
wherein the second lower main face of the first substrate corresponds to the second lower main face of the second metallic layer of the first substrate.

20. The semiconductor package of claim 1,
wherein the first substrate comprises at least one of a copper alloy, a copper composite, an aluminum alloy, or an aluminum composite.

21. A method for producing a semiconductor package, the method comprising:
providing a first substrate comprising a first upper main face and a second lower main face;
disposing a semiconductor chip on the first substrate, the semiconductor chip comprising a first upper main face and a second lower main face, wherein the second lower main face of the semiconductor chip is disposed on the first upper main face of the first substrate;
electrically connecting a leadframe with the semiconductor chip, the leadframe comprising at least one lead disposed on a side of the semiconductor package, the at least one lead being electrically connected with the semiconductor chip; and
applying an encapsulant to the first substrate, the semiconductor chip and the leadframe, the encapsulant comprising a first upper main face and a second lower main face,
wherein the second lower main face of the encapsulant comprises a first portion extending in a first plane, a second portion extending in a second plane, a third portion extending in a first transition zone between the first plane and the second plane, and a fourth portion extending in a second transition zone between the second plane and the at least one lead,
wherein both the first portion of the second lower main face of the encapsulant and the second lower main face of the first substrate extend in the first plane, the first plane forming a lower heat dissipation surface of the semiconductor package,
wherein the second portion, the third portion and the fourth portion of the second lower main face of the encapsulant are dimensioned so as to keep a predefined minimum distance between the first portion of the second lower main face of the encapsulant and the at least one lead.
